(19) United States
(12) Patent Application Publication
(10) Pub. No.: US 2026/0155803 A1
(43) Pub. Date: Jun. 4, 2026

(54) ELECTRONIC COMPONENT

(71) Applicant: TDK CORPORATION, Tokyo (JP)

(72) Inventors: Takuya Sato, Tokyo (JP); Kazuhiro Tsukamoto, Tokyo (JP)

(73) Assignee: TDK CORPORATION, Tokyo (JP)

(21) Appl. No.: 19/389,849

(22) Filed: Nov. 14, 2025

(30) Foreign Application Priority Data
Dec. 2, 2024 (JP) 2024-209404

(51) Int. Cl. H03H 7/01

(52) U.S. Cl. CPC H03H 7/0161; H03H 7/1775

(57) ABSTRACT

An electronic component includes a first main body, and a second main body being mounted on the first main body and including an acoustic wave element. The first main body includes an input port, an output port, and a first circuit section being provided between the input port and the output port in a circuit configuration and including a low-pass filter and a high-pass filter. The acoustic wave element is provided between the first circuit section and the output port in the circuit configuration.

### CROSS REFERENCE TO RELATED APPLICATIONS

This application claims the benefit of Japanese Priority Patent Application No. 2024-209404 filed on Dec. 2, 2024, the entire contents of which are incorporated herein by reference.

### BACKGROUND

The disclosure relates to an electronic component including a filter including an acoustic wave element.

A filter such as a low-pass filter, a high-pass filter, or a band-pass filter includes a plurality of resonators. As the resonators used for such a filter, for example, an LC resonator including an inductor and a capacitor and an acoustic wave resonator including an acoustic wave element are known. The acoustic wave element is an element using an acoustic wave. Examples of the acoustic wave element include a surface acoustic wave element using a surface acoustic wave and a bulk acoustic wave element using a bulk acoustic wave.

JP 2020-28013 discloses a filter including a filter circuit including a series-arm resonator and a parallel-arm resonator, each of which includes an acoustic wave resonator. The series-arm resonator is arranged in a signal path coupling two input/output terminals. The parallel-arm resonator is connected between one end of a circuit forming at least a part of the signal path and a ground. The filter further includes a matching circuit connected to the filter circuit, the matching circuit including a capacitor and an inductor that are connected to each other in parallel.

In a filter device, when a signal having a frequency lower than a passband is input, harmonics having frequencies that are integral multiples of the above-mentioned signal may be generated in a filter section including an acoustic wave element. When a frequency of the harmonics falls within the passband of the filter section, the harmonics are superimposed as noise on a signal to be extracted by the filter device. As a result, there has been a problem of degradation of the characteristics of the filter device. In particular, in a filter device using an acoustic wave element, there has been a problem in that harmonics are more likely to be generated as compared to a filter device using an LC resonator.

The above-mentioned problems are not limited to the filter device, but is also applicable to a branching filter or the like including an acoustic wave element.

### SUMMARY

An electronic component according to one embodiment of the disclosure includes a first main body, and a second main body being mounted on the first main body and including an acoustic wave element. The first main body includes an input port, an output port, and a first circuit section being provided between the input port and the output port in a circuit configuration and including a low-pass filter and a high-pass filter. The acoustic wave element is provided between the first circuit section and the output port in the circuit configuration.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a block diagram showing a configuration of an electronic component according to an example embodiment of the disclosure.

FIG. 2 is a circuit diagram showing an example of a circuit configuration of the electronic component according to the example embodiment of the disclosure.

FIG. 3 is a perspective view showing the electronic component according to the example embodiment of the disclosure.

FIG. 4 is a perspective view showing a first main body in the example embodiment of the disclosure.

FIG. 5 is a perspective view showing the first main body in the example embodiment of the disclosure.

FIG. 6 is a characteristic chart showing the pass attenuation characteristics of the electronic component according to the example embodiment of the disclosure.

### DETAILED DESCRIPTION

An object of the disclosure is to provide an electronic component that can suppress a problem caused by an acoustic wave element.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

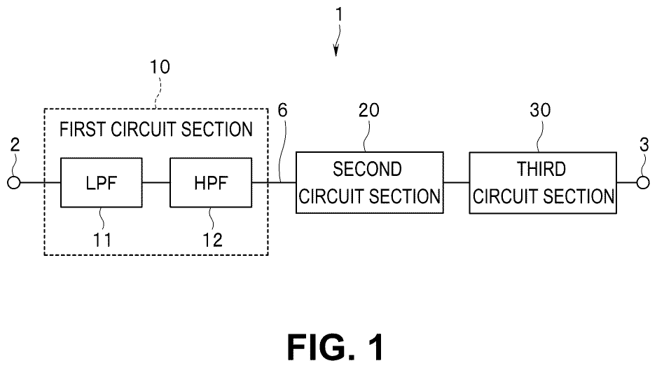

First, with reference to FIG. 1, a configuration of an electronic component 1 according to an example embodiment of the disclosure is described. FIG. 1 is a block diagram showing the configuration of the electronic component 1 according to the example embodiment. The electronic component 1 according to the example embodiment is configured to function as a band-pass filter that selectively passes a signal having a frequency within a predetermined passband.

The electronic component 1 according to the example embodiment includes a first port 2, a second port 3, and a first circuit section 10, a second circuit section 20, and a third circuit section 30 that are provided between the first port 2 and the second port 3 in a circuit configuration. The first port 2 corresponds to an “input port” in the disclosure. The second port 3 corresponds to an “output port” in the disclosure. In the example embodiment, in particular, the first port 2 may be a port for connection to an antenna. The second port 3 may be a port for connection to at least one of a transmission circuit for processing a transmission signal and a reception circuit for processing a reception signal. Note that, in the example embodiment, the expression “in the (a) circuit configuration” is used to indicate layout in a circuit diagram, not in a physical configuration.

The first circuit section 10, the second circuit section 20, and the third circuit section 30 are provided in the stated order from the first port 2 to the second port 3. The first circuit section 10 includes a first filter 11 and a second filter 12. The first filter 11 is connected to the first port 2. The second filter 12 is provided between the first filter 11 and the second circuit section 20 in the circuit configuration.

Each of the first filter 11 and the second filter 12 includes an LC filter circuit including at least one inductor and at least one capacitor. An order of at least one of the first filter 11 and the second filter 12 may be a third order or higher.

The first filter 11 may be a low-pass filter. In such a case, the first filter 11 is preferably a low-pass filter of a third order or higher, more preferably, a low-pass filter of a fifth order or higher.

The second filter 12 may be a high-pass filter. In such a case, the second filter 12 is preferably a high-pass filter of a third order or higher, more preferably, a high-pass filter of a fifth order or higher.

FIG. 1 shows an example in which the first filter 11 is a low-pass filter and the second filter 12 is a high-pass filter. In such a case, the first circuit section 10 as a whole serves as a band-pass filter.

The electronic component 1 further includes at least one acoustic wave element. The at least one acoustic wave element is provided between the first circuit section 10 and the second port 3 in the circuit configuration. The at least one acoustic wave element may be provided in the second circuit section 20, may be provided in the third circuit section 30, or may be provided in both the second circuit section 20 and the third circuit section 30.

Description is made below on a case in which the at least one acoustic wave element is provided in the second circuit section 20 as an example. In such a case, the third circuit section 30 may include a high-pass filter. The high-pass filter may include an LC filter circuit including at least one inductor and at least one capacitor.

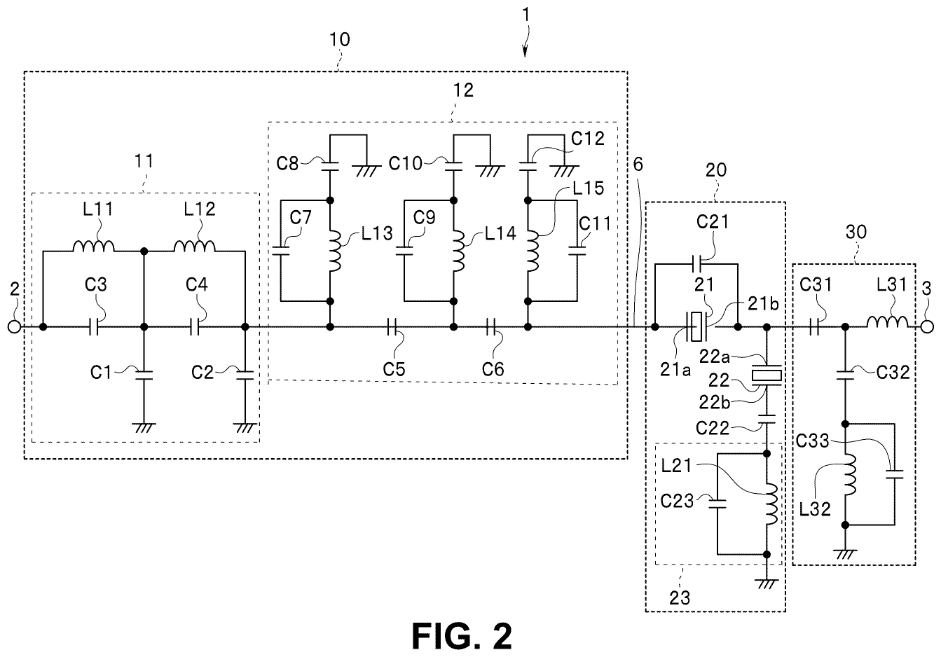

Next, with reference to FIG. 2, an example of a circuit configuration of the electronic component 1 is described. FIG. 2 is a circuit diagram showing the circuit configuration of the electronic component 1. At least a part of the circuit shown in FIG. 2 may be an actual circuit of the electronic component 1, or may be an equivalent circuit of the electronic component 1. First, a configuration of the first circuit section 10 is described. The first filter 11 of the first circuit section 10 includes inductors L11 and L12, and capacitors C1, C2, C3, and C4. One end of the inductor L11 is connected to the first port 2. One end of the inductor L12 is connected to the other end of the inductor L11.

One end of the capacitor C1 is connected to a connection point between the inductor L11 and the inductor L12. One end of the capacitor C2 is connected to the other end of the inductor L12. The other end of each of the capacitors C1 and C2 is connected to the ground.

The capacitor C3 is connected in parallel to the inductor L11. The capacitor C4 is connected in parallel to the inductor L12.

The second filter 12 of the first circuit section 10 includes inductors L13, L14, and L15, and capacitors C5, C6, C7, C8, C9, C10, C11, and C12. One end of the capacitor C5 is connected to the other end of the inductor L12 of the first filter 11. One end of the capacitor C6 is connected to the other end of the capacitor C5.

One end of the inductor L13 is connected to the one end of the capacitor C5. The capacitor C7 is connected in parallel to the inductor L13. One end of the capacitor C8 is connected to the other end of the inductor L13. The other end of the capacitor C8 is connected to the ground.

One end of the inductor L14 is connected to a connection point between the capacitor C5 and the capacitor C6. The capacitor C9 is connected in parallel to the inductor L14. One end of the capacitor C10 is connected to the other end of the inductor L14. The other end of the capacitor C10 is connected to the ground.

One end of the inductor L15 is connected to the other end of the capacitor C6. The capacitor C11 is connected in parallel to the inductor L15. One end of the capacitor C12 is connected to the other end of the inductor L15. The other end of the capacitor C12 is connected to the ground.

Next, the second circuit section 20 is described. The second circuit section 20 includes capacitors C21 and C22, and acoustic wave elements 21 and 22. The second circuit section 20 is provided between the first circuit section 10 and the second port 3 in the circuit configuration. Thus, it can also be understood that the acoustic wave elements 21 and 22 are provided between the first circuit section 10 and the second port 3 in the circuit configuration.

The acoustic wave element 21 is provided in a path connecting the first port 2 and the second port 3 to each other in the circuit configuration, in other words, a path 6 from the first port 2 to the second port 3 in the circuit configuration. The acoustic wave element 22 is provided between the path 6 and the ground in the circuit configuration. The capacitor C21 is connected in parallel to the acoustic wave element 21. The capacitor C22 is provided between the acoustic wave element 22 and the ground in the circuit configuration.

The acoustic wave element 21 includes a first end 21a, a second end 21b located opposite to the first end 21a. The acoustic wave element 22 includes a third end 22a and a fourth end 22b located opposite to the third end 22a. The first end 21a of the acoustic wave element 21 is connected to the other end of the capacitor C6 of the second filter 12. The second end 21b of the acoustic wave element 21 and the third end 22a of the acoustic wave element 22 are connected to each other. One end of the capacitor C22 is connected to the fourth end 22b of the acoustic wave element 22.

The second circuit section 20 further includes an LC parallel circuit 23 in which an inductor and a capacitor are connected in parallel to each other. The LC parallel circuit 23 is provided between the acoustic wave element 22 and the ground in the circuit configuration. In the example embodiment, in particular, the LC parallel circuit 23 includes an inductor L21 and a capacitor C23. One end of the inductor L21 is connected to the other end of the capacitor C22. The capacitor C23 is connected in parallel to the inductor L21. The other end of the inductor L21 is connected to the ground.

Next, the third circuit section 30 is described. The third circuit section 30 includes inductors L31 and L32, and capacitors C31, C32, and C33. One end of the capacitor C31 is connected to the second end 21b of the acoustic wave element 21 of the second circuit section 20. One end of the inductor L31 is connected to the other end of the capacitor C31. The other end of the inductor L31 is connected to the second port 3.

One end of the capacitor C32 is connected to the other end of the capacitor C31. One end of the inductor L32 is connected to the other end of the capacitor C32. The capacitor C33 is connected in parallel to the inductor L32. The other end of the inductor L32 is connected to the ground.

In the example shown in FIG. 2, no other acoustic wave element than the acoustic wave element 21 is provided in the path 6 connecting the first port 2 and the second port 3 to each other. No other acoustic wave element than the acoustic wave element 22 is provided between the path 6 and the ground in the circuit configuration.

In the example shown in FIG. 2, each of the acoustic wave elements 21 and 22 is not electrically connected to the ground. In other words, among conductors in the path from each of the first end 21a and the second end 21b of the acoustic wave element 21 to the ground, a section electrically connected to the first end 21a and a section electrically connected to the second end 21b are not electrically connected to the ground due to at least one capacitor present in the path. Similarly, among conductors in the path from each of the third end 22a and the fourth end 22b of the acoustic wave element 22 to the ground, a section electrically connected to the third end 22a and a section electrically connected to the fourth end 22b are not electrically connected to the ground due to at least one capacitor present in the path.

While focusing on the acoustic wave element 21, the electronic component 1 includes a first path from the first end 21a of the acoustic wave element 21 to the ground and a second path from the second end 21b of the acoustic wave element 21 to the ground, which does not pass through the same elements in the first path and the acoustic wave element 22, in the circuit configuration. Among the conductors in the first path, the section electrically connected to the first end 21a of the acoustic wave element 21 is not electrically connected to the ground due to the capacitor C6, the capacitor C12, or the capacitor C21 present in the first path. Among the conductors in the second path, the section electrically connected to the second end 21b of the acoustic wave element 21 is not electrically connected to the ground due to the capacitor C21 or the capacitor C31 present in the second path.

While focusing on the acoustic wave element 22, the electronic component 1 includes a third path from the third end 22a of the acoustic wave element 22 to the ground, which does not pass through the acoustic wave element 21, and a fourth path from the fourth end 22b of the acoustic wave element 22 to the ground in the circuit configuration. Among the conductors in the third path, the section connected to the third end 22a of the acoustic wave element 22 is not electrically connected to the ground due to the capacitor C21 or the capacitor C31 present in the third path. Among the conductors in the fourth path, the section connected to the fourth end 22b of the acoustic wave element 22 is not electrically connected to the ground due to the capacitor C22 present in the fourth path.

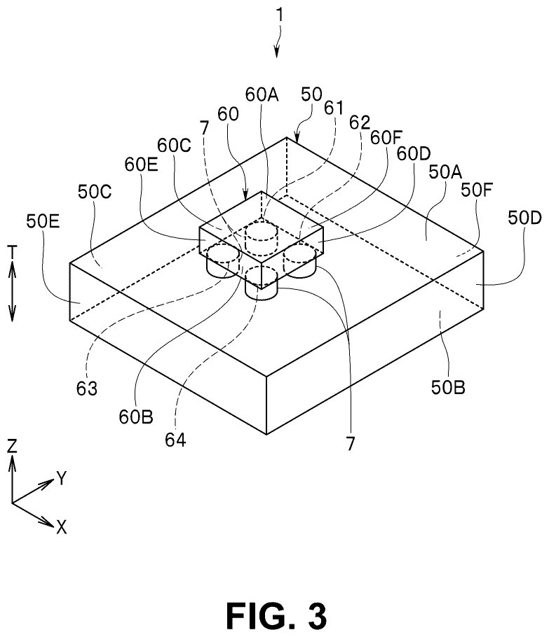

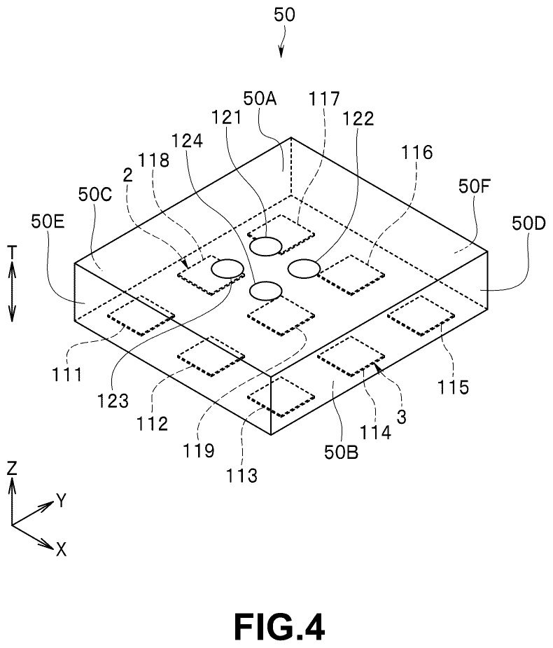

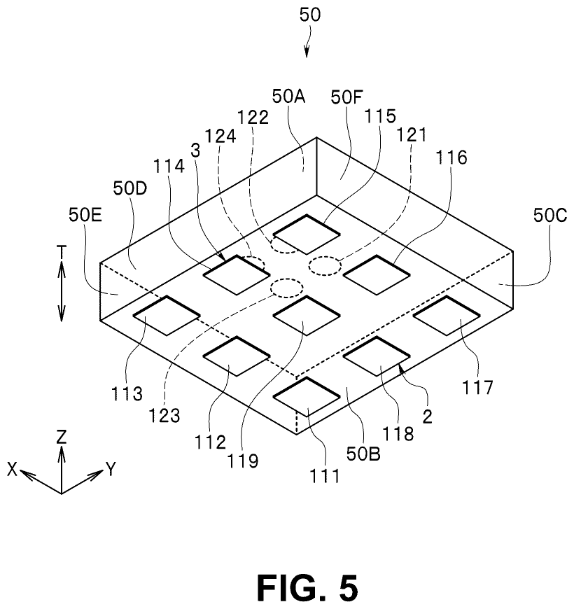

Next, other configurations of the electronic component 1 will be described with reference to FIG. 1 to FIG. 5. FIG. 3 is a perspective view showing the electronic component 1. FIG. 4 and FIG. 5 are each a perspective view showing a first main body. The electronic component 1 according to the example embodiment includes a first main body 50 and a second main body 60 mounted on the first main body 50.

First, a configuration of the first main body 50 is described. The first main body 50 includes a plurality of dielectric layers being stacked and a plurality of conductors (a plurality of conductor layers and a plurality of through holes). Each of the plurality of dielectric layers includes a dielectric material. As such a dielectric material, for example, a low temperature co-fired ceramic (LTCC) is used.

The inductors L11 to L15, L21, L31, and L32 and the capacitors C1 to C12, C21 to C23, and C31 to C33 shown in FIG. 2 are configured by a plurality of conductors provided in the first main body 50. In other words, the first main body 50 includes the inductors L11 to L15, L21, L31, and L32 and the capacitors C1 to C12, C21 to C23, and C31 to C33.

The inductors L11 and L12 and the capacitors C1 to C4 are constituent elements of the first filter 11 shown in FIG. 1, the inductors L13 to L15 and the capacitors C5 to C12 are constituent elements of the second filter 12 shown in FIG. 1, and the first filter 11 and the second filter 12 are constituent elements of the first circuit section 10 shown in FIG. 1. Therefore, it can also be understood that the first main body 50 includes the first filter 11 and the second filter 12, and also includes the first circuit section 10.

The inductor L21 and the capacitors C21 to C23 are parts of constituent elements of the second circuit section 20 shown in FIG. 1, and corresponds to parts of the second circuit section 20 where the acoustic wave elements 21 and 22 are excluded. Therefore, it can also be understood that the first main body 50 includes a part of constituent elements of the second circuit section 20, in other words, a part of the second circuit section 20 where the acoustic wave elements 21 and 22 are excluded.

The inductors L31 and L32 and the capacitors C31 to C33 are constituent elements of the third circuit section 30 shown in FIG. 1. Therefore, it can also be understood that the first main body 50 includes the third circuit section 30.

The first main body 50 includes a first surface 50A and a second surface 50B located at opposite ends in a stacking direction T of the plurality of dielectric layers, and four side surfaces 50C to 50F connecting the first surface 50A and the second surface 50B to each other. The side surfaces 50C and 50D are opposite to each other, and also the side surfaces 50E and 50F are opposite to each other. The side surfaces 50C to 50F each are perpendicular to the first surface 50A and the second surface 50B.

Here, X, Y, and Z directions are defined as shown in FIGS. 3 to 5. The X direction, the Y direction, and the Z direction are orthogonal to one another. In the example embodiment, a direction parallel to the stacking direction T is referred to as the Z direction. The Z direction is also one direction parallel to a direction in which the first main body 50 and the second main body 60 are arranged. The opposite directions to the X, Y, and Z directions are defined as −X, −Y, and −Z directions, respectively. The expression “when seen in a predetermined direction (for example, the stacking direction T)” means that an intended object is seen from a position at a distance in the predetermined direction or a direction parallel to the predetermined direction, in other words, an intended object is seen in plan view from a position at a distance in the predetermined direction or a direction parallel to the predetermined direction.

As shown in FIG. 3 to FIG. 5, the first surface 50A is located at the end of the first main body 50 in the Z direction. The first surface 50A is also a top surface of the first main body 50, and is also a surface for the second main body 60 to be mounted on. The second surface 50B is located at the end of the first main body 50 in the −Z direction. The second surface 50B is also a bottom surface of the first main body 50. FIG. 4 shows the first main body 50 in a view from the first surface 50A side. FIG. 5 shows the first main body 50 in a view from the second surface 50B side.

The side surface 50C is located at the end of the first main body 50 in the −X direction. The side surface 50D is located at the end of the first main body 50 in the X direction. The side surface 50E is located at the end of the first main body 50 in the −Y direction. The side surface 50F is located at the end of the first main body 50 in the Y direction.

The first main body 50 further includes a plurality of electrodes 111, 112, 113, 114, 115, 116, 117, 118, and 119 provided on the second surface 50B of the first main body 50. The electrodes 111, 112, and 113 are arranged in this order in the X direction at positions closer to the side surface 50E than to the side surface 50F. The electrodes 115, 116, and 117 are arranged in this order in the −X direction at positions closer to the side surface 50F than to the side surface 50E.

The electrode 114 is arranged between the electrode 113 and electrode 115. The electrode 118 is arranged between the electrode 111 and the electrode 117. The electrode 119 is arranged between the electrode 112 and the electrode 116. The electrode 119 is arranged substantially at the center of the second surface 50B.

The electrode 118 corresponds to the first port 2. The electrode 114 corresponds to the second port 3. Therefore, the first port 2 and the second port 3 are provided on the second surface 50B of the first main body 50. Each of the electrodes 111, 112, 113, 115, 116, 117, and 119 is connected to the ground.

The first main body 50 further includes four electrodes 121, 122, 123, and 124 provided on the first surface 50A of the first main body 50. The electrodes 121 and 122 are arrayed in the X direction in this order. The electrodes 123 and 124, at positions beyond the electrodes 121 and 122 in the −Y direction, are arranged in this order in the X direction.

In the example embodiment, the electrode 121 is arranged at a position closer to the electrode 123 than to the electrode 124. The electrode 122 is arranged at a position closer to the electrode 124 than to the electrode 123.

Next, a configuration of the second main body 60 is described. The second main body 60 includes the acoustic wave elements 21 and 22 shown in FIG. 2. The second main body 60 includes a third surface 60A and a fourth surface 60B located at opposite ends in the stacking direction T, and four side surfaces 60C, 60D, 60E, and 60F connecting the third surface 60A and the fourth surface 60B to each other. The four side surfaces 60C to 60F each are perpendicular to the third surface 60A and the fourth surface 60B.

The third surface 60A is located at the end of the second main body 60 in the Z direction. The third surface 60A is also a top surface of the second main body 60. The fourth surface 60B is located at the end of the second main body 60 in the −Z direction. The fourth surface 60B is also a bottom surface of the second main body 60, and is also a counter surface facing the first surface 50A of the first main body 50.

The second main body 60 further includes four terminals 61, 62, 63, and 64 provided on the fourth surface 60B. While the second main body 60 is mounted on the first main body 50, the terminals 61 to 64 face the electrodes 121 to 124 of the first main body 50, respectively. For example, the terminals 61 to 64 are physically connected to the electrodes 121 to 124 by solder bumps 7.

The first end 21a of the acoustic wave element 21 is connected to the terminal 61. The second end 21b of the acoustic wave element 21 is connected to the terminal 62. The third end 22a of the acoustic wave element 22 is connected to the terminal 63. The fourth end 22b of the acoustic wave element 22 is connected to the terminal 64. The terminals 61 to 64 are connected to the electrodes 121 to 124, respectively. Thus, the first end 21a of the acoustic wave element 21, the second end 21b of the acoustic wave element 21, the third end 22a of the acoustic wave element 22, and the fourth end 22b of the acoustic wave element 22 are connected to the electrodes 121, 122, 123, and 124, respectively.

The electronic component 1 may further include a seal that seals the second main body 60, which is omitted in illustration. The seal may cover the periphery of the second main body 60 and at least a part of the first surface 50A of the first main body 50. The seal may further cover the side surfaces 50C to 50F of the first main body 50. The seal may be formed of an insulating material containing a resin, for example.

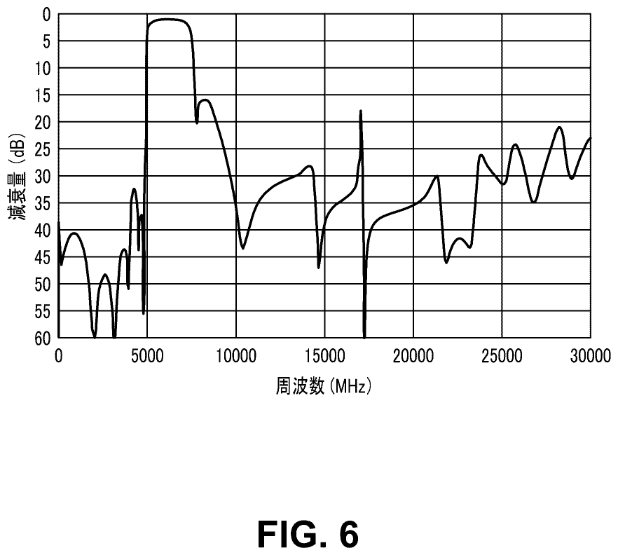

Next, an example of the characteristics of the electronic component 1 according to the example embodiment is described. FIG. 6 is a characteristic chart showing the pass attenuation characteristics of the electronic component 1. In FIG. 6, the horizontal axis indicates frequency and the vertical axis indicates attenuation. In the transmission attenuation characteristics shown in FIG. 6, a frequency region in which an absolute value of attenuation is a value close to 0 represents a passband of the electronic component 1. FIG. 6 shows the characteristics of the electronic component 1 when the passband of the electronic component 1 is designed to include a frequency band of 5,150 MHz to 7,125 MHz. From FIG. 6, it is understood that the electronic component 1 according to the example embodiment has practically sufficient characteristics as a band-pass filter.

Next, the operation and effects of the electronic component 1 according to the example embodiment are described. In the example embodiment, the first main body 50 includes the first port 2, the second port 3, and the first circuit section 10 that is provided between the first port 2 and the second port 3 in the circuit configuration and includes the first filter 11 and the second filter 12. The acoustic wave elements 21 and 22 are provided between the first circuit section 10 and the second port 3 in the circuit configuration. In the example embodiment, in particular, the first filter 11 is a low-pass filter, and the second filter 12 is a high-pass filter.

Here, a case in which a signal having a frequency lower than a signal in the passband of the electronic component 1 is input to the second circuit section 20 from the first port 2 side is considered. The acoustic wave elements 21 and 22 are provided in the second circuit section 20. Thus, harmonics having a frequency that is integral multiples of the above-mentioned signal may be generated in the second circuit section 20 due to the acoustic wave elements 21 and 22. For example, when a frequency of the signal that is input to the second circuit section 20 is 2.5 GHz, harmonics of 5 GHz may be generated as secondary harmonics. When the passband of the electronic component 1 is a frequency band in the vicinity of 5 GHz, the harmonics is superimposed as noise on a signal to be extracted by the electronic component 1. As a result, the characteristics of the electronic component 1 are degraded.

In contrast, in the example embodiment, the acoustic wave elements 21 and 22 are provided between the first circuit section 10 and the second port 3. A signal that is input to the first port 2 is input to the second circuit section 20 including the acoustic wave elements 21 and 22 via the first circuit section 10. The first circuit section 10 includes a high-pass filter. In the example embodiment, in particular, the second filter 12 is a high-pass filter. According to the example embodiment, a signal causing the harmonics described above can be removed by the high-pass filter. With this, according to the example embodiment, a problem due to the harmonics caused by the acoustic wave elements 21 and 22 can be suppressed.

In the example embodiment, the second circuit section 20 may be configured as a filter in which the passband of the second circuit section 20 includes a frequency that is 1.5 to 3 times a cutoff frequency of the high-pass filter (the second filter 12). With this, according to the example embodiment, a problem mainly caused by secondary harmonics can be suppressed.

In the example embodiment, each of the first filter 11 and the second filter 12 of the first circuit section 10 is an LC filter circuit provided in the first main body 50. The LC filter circuit can suppress generation of the harmonics as compared to a filter circuit including an acoustic wave element. With this, according to the example embodiment, a problem due to the harmonics can also be suppressed.

Incidentally, in the example embodiment, each of the acoustic wave elements 21 and 22 is not electrically connected to the ground. Further, in the example embodiment, the acoustic wave elements 21 and 22 are not electrically connected to the first and second ports 2 and 3, respectively. In the example embodiment, in particular, the first port 2 and the second port 3 are not electrically connected to each other, and the electrode 118 corresponding to the first port 2 and the electrode 114 corresponding to the second port 3 are not electrically connected to other electrodes. With this configuration described above, in the example embodiment, even when static electricity is discharged in the vicinity of the electronic component 1, and a voltage is applied to the electrodes 111 to 119, no current flows in the acoustic wave elements 21 and 22. With this, according to the example embodiment, a problem caused by damage to the acoustic wave elements 21 and 22 due to static electricity can be suppressed.

Note that the disclosure is not limited to the foregoing example embodiment, and various modifications may be made thereto. The disclosure is not limited to the electronic component including the circuit configuration shown in FIG. 2, and is applicable to electronic components including various circuit configurations as long as the requirements of the claims are satisfied. For example, the number of acoustic wave elements included in the electronic component 1 may be three or more.

At least one of the first filter 11 and the second filter 12 may be a filter other than a low-pass filter or a high-pass filter, such as a band-pass filter.

The electronic component 1 may be used so that a signal is input from the second port 3.

As described above, an electronic component according to one embodiment of the disclosure includes a first main body, and a second main body being mounted on the first main body and including an acoustic wave element. The first main body includes an input port, an output port, and a first circuit section being provided between the input port and the output port in a circuit configuration and including a low-pass filter and a high-pass filter. The acoustic wave element is provided between the first circuit section and the output port in the circuit configuration.

In the electronic component according to one embodiment of the disclosure, the input port may be a port for connection to an antenna. The output port may be a port for connection to at least one of a transmission circuit for processing a transmission signal and a reception circuit for processing a reception signal.

In the electronic component according to one embodiment of the disclosure, the low-pass filter may be provided between the input port and the high-pass filter in the circuit configuration.

In the electronic component according to one embodiment of the disclosure, an order of at least one of the low-pass filter and the high-pass filter may be a third order or higher.

The electronic component according to one embodiment of the disclosure may further include a second circuit section including the acoustic wave element. A passband of the second circuit section may include a frequency that is 1.5 to 3 times a cutoff frequency of the high-pass filter.

In the electronic component according to one embodiment of the disclosure, the acoustic wave element may be provided in a path connecting the input port and the output port to each other.

In the electronic component according to one embodiment of the disclosure, the first main body may further include a capacitor. The capacitor may be connected in parallel to the acoustic wave element.

In the electronic component according to one embodiment of the disclosure, no other acoustic wave element than the acoustic wave element may be provided in the path connecting the input port and the output port to each other.

In the electronic component according to one embodiment of the disclosure, the acoustic wave element may be provided between the path connecting the input port and the output port to each other and the ground in the circuit configuration.

In the electronic component according to one embodiment of the disclosure, the first main body may further include a capacitor. The capacitor may be provided between the acoustic wave element and the ground in the circuit configuration.

In the electronic component according to one embodiment of the disclosure, the first main body may further include an LC parallel circuit in which an inductor and a capacitor are connected in parallel to each other. The LC parallel circuit may be provided between the acoustic wave element and the ground in the circuit configuration.

In the electronic component according to one embodiment of the disclosure, no other acoustic wave element may be provided between the path connecting the input port and the output port to each other and the ground in the circuit configuration.

In an electronic component of the disclosure, a first main body includes an input port, an output port, and a first circuit section being provided between the input port and the output port in a circuit configuration and including a low-pass filter and a high-pass filter. An acoustic wave element is provided between the first circuit section and the output port in the circuit configuration. With this, according to the disclosure, an electronic component that can suppress a problem caused by an acoustic wave element can be achieved.

Obviously, various aspects and modification examples of the disclosure can be practiced in the light of the above teachings. Thus, it is to be understood that, within the scope of the appended claims and equivalents thereof, the disclosure can be practiced in other forms than the foregoing example embodiments.

1. An electronic component comprising:

[symbol]

2. The electronic component according to claim 1, wherein

[symbol]

3. The electronic component according to claim 1, wherein

[symbol]

4. The electronic component according to claim 1, wherein

[symbol]

5. The electronic component according to claim 1, further comprising:

[symbol]

6. The electronic component according to claim 1, wherein

[symbol]

7. The electronic component according to claim 6, wherein

[symbol]

8. The electronic component according to claim 6, wherein

[symbol]

9. The electronic component according to claim 1, wherein

[symbol]

10. The electronic component according to claim 9, wherein

[symbol]

11. The electronic component according to claim 9, wherein

[symbol]

12. The electronic component according to claim 9, wherein [symbol]
